(19) United States
(12) Patent Application Publication
(10) Pub. No.: US 2011/0045638 A1
(43) Pub. Date: Feb. 24, 2011

(54) HEAT RESISTANT MASKING TAPE AND USAGE THEREOF

(76) Inventors: Yorinobu Takamatsu, Kanagawa-ken (JP); Rina Mawatari, Kanagawa-ken (JP); Yuka Uchida, Tokyo (JP); Masaru Shinohara, Tokyo (JP)

Correspondence Address: 3M INNOVATIVE PROPERTIES COMPANY, PO BOX 33427, ST. PAUL, MN, 55133-3427, US

(21) Appl. No.: 12/516,109

(22) PCT Filed: Nov. 28, 2007
(86) PCT No.: PCT/US07/85702

§ 371 Date: May 22, 2009

(30) Foreign Application Priority Data
Dec. 11, 2006 (JP) 2006-333151

(51) Int. Cl. H01L 21/56; C09J 7/02; B32B 27/30; H01L 21/60

(52) U.S. Cl. 438/118; 428/355 AC; 257/E21.502; 257/E21.506

(57) ABSTRACT

The present invention provides a masking tape which can be easily released without leaving an adhesive residue. A heat resistant masking tape, comprising (1) a heat resistant backing film layer, and (2) a pressure-sensitive adhesive layer disposed on the heat resistant backing film layer, wherein the adhesive layer comprises a polymer having a solubility parameter (SP) value at 25° C. of 20 MPa^{0.5} or less.

### TECHNICAL FIELD

The present invention relates to a heat resistant masking material and a usage thereof.

### BACKGROUND

In general, an adhesive tape comprising a backing layer and an adhesive layer containing an acrylic polymer as a main component formed on backing layer is used for various purposes. An acrylic adhesive is generally superior in weatherability, and in case when the acrylic adhesive is cross linked, it becomes possible to be provided with the heat resistance.

An example of the crosslink-type acrylic adhesive is disclosed in the specification of U.S. Pat. No. 3,284,423. This crosslink-type acrylic adhesive contains (a) 35 to 75% by weight of an acrylate ester having 6 to 15 carbon atoms, (b) 10 to 60% by weight of methyl acrylate or ethyl acrylate, (c) 0.1 to 10% by weight of an acid component such as (meth)acrylic acid, itaconic acid or crotonic acid, and (d) 0.1 to 10% by weight of glycidyl (meth)acrylate, and is self-crosslinked at room temperature or upon heating. As a result, the crosslink-type acrylic adhesive can have both a cohesive force and a holding force and a sufficiently high adhesive force at high temperature. Preferably, glycidyl (meth)acrylate is present in an amount of 1 to 3% by weight, thereby to impart a desired cohesive force to the above crosslink-type acrylic adhesive.

Further, Japanese Patent No. 2,955,095 discloses an adhesive for a surface protecting film, comprising a copolymer derived from copolymerizing a (meth)acrylate ester monomer with a carboxylic group-containing copolymerizable monomer, the copolymer being crosslinked by an epoxy compound having two or more epoxy groups per one molecule, such as polyglycidyl ether or polyglycidyl amine, wherein the adhesive after crosslinking has a 10% modulus of 0.8 to 4.0 kgf/cm². It describes that the adhesive is used for protecting a surface of a resinous board. It further describes that it allows a high-speed release of the protecting film with the adhesive from the resinous board, by adjusting the modulus of the adhesive to 0.8 kg/cm² or more.

The specification of U.S. Pat. No. 3,729,338 discloses a self-adhesive tape produced by coating a material, prepared by adding a small amount of a catalyst and/or a polyfunctional compound to a low molecular weight copolymer comprising (a) 85 to 99.95% by weight of an alkyl acrylate having 4 to 12 carbon atoms, and (b) 0.05 to 15 parts by weight of a copolymerizable monomer having one or more reactive groups in addition to a double bond, on a base material and curing the material upon heating. This document describes that this adhesive tape has good adhesion and good heat resistance. Glycidyl methacrylate and (meth)acrylic acid are used as the monomer having reactive groups, and an acid such as octylphosphoric acid or p-toluenesulfonic acid, and a metal compound such as zinc chloride or dibutyltin dilaurate are used as the catalyst.

Japanese Unexamined Patent Publication (kokai) No. 2005-53975 discloses a heat resistant masking tape comprising (1) heat resistant backing film layer, and (2) an adhesive layer disposed on the heat resistant backing film layer, wherein the adhesive layer comprises a polymer resulting from polymerizing and crosslinking a monomer mixture comprising an alkyl (meth)acrylate with an alkyl group having 4 to 15 carbon atoms, glycidyl (meth)acrylate and (meth)acrylic acid, the glycidyl (meth)acrylate being present in an amount of 2 to 13% by weight of the total weight of monomers and the (meth)acrylic acid being present in an amount of 1 to 7% by weight of the total weight of monomers. Specifically, n-butyl acrylate is mainly used as the alkyl (meth)acrylate.

However, when a trial of packaging using an epoxy molding compound (EMC) is made in the process for manufacturing a chip scale package (CSP) in which the above adhesive tapes comprising an adhesive described in the above mentioned patent documents and a lead frame is used, inconveniences in use may arise under the following unexpected conditions. It is assumed that the above adhesive is not subjected to the temperature of higher than 150° C. encountered in CPS, and as it has insufficient adhesion force at high temperature. Also, it becomes difficult to release the masking tape after the step of curing of EMC upon heating because of high affinity between the adhesive and EMC. It is difficult to release the masking tape from EMC and thus an adhesive residue is left on the package. In such a case, the step of cleaning the package becomes necessary, resulting in high manufacturing cost.

### SUMMARY

In the field of masking tape etc. for lead frame used such as in manufacturing of a chip-scale packaging, an adhesive tape capable of resisting increasingly severe conditions is required. For example, an adhesive masking tape is required that has a sufficient initial adhesion to an adherent and a cohesive force for repositionability, has a stable adhesive strength at time heat treatment at a high temperature for an extended time and plasma treatment, and can later be easily released without leaving an adhesive residue. The object of the present invention is to provide a masking tape which satisfies such requirements.

The present invention, in one embodiment, provides a heat resistant masking tape, comprising (1) a heat resistant backing film layer, and (2) a pressure-sensitive adhesive layer disposed on the heat resistant backing film layer, wherein the adhesive layer comprises a polymer having a solubility parameter (SP) value at 25° C. of 20 MPa^{0.5} or less.

The present invention, in another embodiment, provides a heat resistant masking tape, comprising (1) a heat resistant backing film layer, and (2) a pressure-sensitive adhesive layer disposed on the heat resistant backing film layer, wherein the adhesive layer comprises a polymer derived from polymerizing a monomer mixture comprising an alkyl (meth)acrylate, (meth)acrylic acid and glycidyl (meth)acrylate, wherein a solubility parameter (SP) value at 25° C. of a homopolymer of the alkyl(meth)acrylate is 19 MPa^{0.5} or less, wherein the alkyl (meth)acrylate is present in an amount of 90 to 99 parts by weight based on 100 parts by weight of the total weight of the alkyl (meth)acrylate and the (meth)acrylic acid, wherein the (meth)acrylic acid is present in an amount of 1 to 10 parts by weight based on 100 parts by weight of the total weight of the alkyl (meth)acrylate and the (meth)acrylic acid, and wherein the glycidyl (meth)acrylate is present in an amount of 0.25 to 2.5 mol based on 1 mol of the (meth)acrylic acid.

The present invention, in another embodiment, provides a method for producing a chip scale package, comprising the steps of laminating a masking tape and a lead frame, mounting a semiconductor chip on the lead frame, electrically connecting the chip, and resin-sealing the packaging using an overmolding compound, wherein the masking tape is the above described heat resistant making tape and the overmolding compound is an epoxy molding compound (EMC).

### BRIEF DESCRIPTION OF THE DRAWINGS

FIGS. 1a-1f show one embodiment of manufacturing process flow diagram of a quad flat non-lead (QFN) chip scale package.

### DETAILED DESCRIPTION

A heat resistant masking tape having an adhesive layer according to the invention can be repositionable, have sufficient adhesion strength after application, will not release or increase adhesion strength such as by an action of heat treatment or plasma treatment, and can be released without residual adhesive after use.

When used as a masking tape to a lead frame for packaging using an epoxy molding compound (hereinafter referred to as “EMC”) in the process for manufacturing a chip scale packaging using a lead frame (hereinafter referred to as “CSP”), the step of cleaning a package is not required because little if any adhesive residue is left on the epoxy molding compound “EMC”.

As used herein, the term “(meth)acrylate” means acrylate or methacrylate, and the term “(meth)acrylic” means acrylic or methacrylic. Further, the term “heat resistant masking tape” is interpreted broadly to encompass a film, sheet or tape.

The heat resistant masking tape of the present invention will now be explained by way of preferred embodiments. It is to be understood by a person with ordinary skill in the art that the present invention is not limited to the specifically described embodiments.

The heat resistant masking tape of the invention comprises a heat resistant backing film layer and a pressure-sensitive adhesive layer disposed on the heat resistant backing film layer. The adhesive layer is disposed on at least one portion of at least one surface of the heat resistant backing film layer. The heat resistant backing film layer supports the adhesive layer. The heat resistant backing film layer may support the acrylic adhesive layer only on one total surface or partial surface thereof, or may support the adhesive layer on both sides of total surfaces or partial surfaces thereof. Commonly, the material for the heat resistant backing film layer is appropriately selected depending on the temperatures the masking tape encounters at time of use. For example, when the temperature encountered during the process is lower than 170° C., a polyethylene terephthalate (PET) film can be selected as a preferable heat resistant backing film layer. When the process temperature is from 170 to 200° C., the preferable heat resistant backing film layer is a film of polyether imide, polyether sulfone, polyethylene naphthalate or polyphenylene sulfide. Furthermore, when the process temperature is about 200° C. or higher, the preferable heat resistant backing film layer is a film of polyether ether ketone, polyamideimide or polyimide. Taking particular account of availability and chemical stability, PET, polyethylene naphthalate, polyphenylene sulfide and polyimide are preferred because of high versatility. Taking account of the handling and availability, the heat resistant backing film layer preferably has a thickness of about 1 to about 250 μm.

The adhesive layer comprises a polymer having a solubility parameter (SP) value at 25° C. of 20 MPa^{0.5} or less.

The adhesive layer comprises a polymer derived from polymerizing and crosslinking a monomer mixture containing.

90 to 99 parts by weight of an alkyl (meth)acrylate (a) in which a solubility parameter value at 25° C. of a homopolymer is 19 MPa^{0.5} or less,

1 to 10 parts by weight of (meth)acrylic acid (b), and

glycidyl (meth)acrylate (c) in an amount of 0.25 to 2.5 mol based on 1 mol of the (meth)acrylic acid (b). The total weight of the alkyl (meth)acrylate and the (meth)acrylic acid in the monomer mixture is 100 parts by weight.

When the content of the alkyl (meth)acrylate in which a solubility parameter (SP) value at 25° C. of a homopolymer is 19 MPa^{0.5} or less is from 90 to 99 parts by weight, the solubility parameter (SP) value at 25° C. of the polymer constituting the adhesive layer is 20 MPa^{0.5} or less. On the other hand, the solubility parameter (SP) value at 25° C. of EMC is commonly from 20.0 to 26.0 MPa^{0.5}. In general, the polymers having closer SP values have high affinity, while the polymers having different SP values have low affinity. It becomes possible to improve releasability of the adhesive from EMC by decreasing the SP value of the polymer constituting the adhesive layer. When the monomer composition is selected to adjust the SP value to 20 MPa^{0.5} or less, the polymer in the adhesive layer can exhibit sufficient releasability of the adhesive layer from EMC after heat treatment.

As used herein, the SP value means an SP value measured at 25° C.

“Solubility parameter (SP) value (6) at 25° C.” is defined by the following equation:

δ=(ΔEv/V)^{0.5}

where ΔEv denotes a molar vaporization energy, and V denotes a molar volume. According to the Fedors's method, the SP value can be calculated only by a chemical structure (See, e.g., R. F. Fedors, A Method for Estimating Both the Solubility Parameters and Molar Volumes of Liquids, Polym. Eng. Sci., 14 (2), p. 147, 1974). Specific calculation examples are shown in examples.

The alkyl (meth)acrylate (a) in which solubility parameter (SP) value at 25° C. of the homopolymer is 19 MPa^{0.5} or less is, for example, 2-ethylhexyl acrylate (SP of its homopolymer=18.9 MPa^{0.5}), isooctyl acrylate (SP of its homopolymer=18.9 MPa^{0.5}), lauryl acrylate (SP of its homopolymer=18.7 MPa^{0.5}), or isobornyl acrylate (SP of its homopolymer=18.6 MPa^{0.5}). n-Butyl acrylate is not suited for use because it has the SP value of 20.0 MPa^{0.5}.

(Meth)acrylic acid (b) is present in an amount of 1 to 10 parts by weight based on 100 parts by weight of the total of the alkyl (meth)acrylate (a) and the (meth)acrylate (b). For example, the SP value of acrylic acid is 26.4 and when the amount of the monomer (b) exceeds 10 parts by weight, the SP value of the polymer increases. On the other hand, when the amount of the monomer (b) is less than 1.0 parts by weight, crosslinking due to the reaction between a carboxyl group of (meth)acrylic acid (b) and a glycidyl group of glycidyl (meth)acrylate (c) is less likely to occur and the heat resistance deteriorates, and adhesive residue is left after use because of poor cohesive force.

The glycidyl (meth)acrylate (c) is present in an amount of 0.25 to 2.5 mol based on 1 mol of the (meth)acrylic acid (b). When the amount is too small, the heat resistance of the adhesive becomes low and an adhesive residue may be left on the adherend after heat treatment. On the other hand, when the amount of the (meth)acrylic acid (b) is too large, delamination may occur during use because of low adhesion to the adherend. Taking account of good balance between the cohesive force of the adhesive layer and adhesion to the adherend, the glycidyl (meth)acrylate is as described above.

The monomer mixture for the polymer constituting the adhesive can contain, in addition to above described monomers (a), (b) and (c), other monomers as far as an adverse influence is not exerted on the effect of the present invention. Specifically, the other monomers include, for example, C₂₋₈ alkyl acrylate such as n-butyl acrylate, isobutyl acrylate, isooctyl acrylate, 2-ethylhexyl acrylate, 2-methylbutyl acrylate, isoamyl acrylate or n-octyl acrylate; and C₈₋₁₅ alkyl methacrylate such as isooctyl methacrylate, 2-ethylhexyl methacrylate, dodecyl methacrylate and/or n-octyl methacrylate. Examples thereof further include alkyl (meth)acrylate such as methyl (meth)acrylate, ethyl methacrylate, stearyl (meth)acrylate, cyclohexyl (meth)acrylate or lauryl acrylate; hydroxyalkyl (meth)acrylate such as hydroxyethyl (meth)acrylate, hydroxypropyl (meth)acrylate or hydroxybutyl (meth)acrylate; and polar monomer such as acrylamide, dimethylaminoethyl (meth)acrylate, N-vinyl pyrrolidone, 2-hydroxy-3-phenoxypropyl acrylate, dimethylaminopropylamide, N,N-dimethylacrylamide, isopropylacrylamide or N-methylolacrylamide.

Heat resistance of the polymer and prevention of an adhesive residue can be exhibited by high cohesive force due to sufficient crosslinking Therefore, it is necessary sufficiently perform the reaction between a carboxyl group of the monomer (b) and a glycidyl group of the monomer (c). Usually, during polymerization, a glycidyl group opens the ring to form a cross-linking with a carboxyl group. In addition, post curing may be performed to increase the degree of crosslinking after polymerization. The post curing step can be performed, for example, at a temperature of 60 to 100° C. for several hours to 3 days. It is also possible to omit the post curing step by mixing the monomer mixture with a curing accelerator. A phosphorus-based curing agent can be used as the curing accelerator and is commonly used in an amount of 0.05 to 5.0% by weight based on the total weight of the monomers. Useful phosphorus-based curing agent includes triphenylphosphine (TPP).

Furthermore, the polymer constituting the adhesive layer preferably has an elastic modulus at 25 or 80° C. of 0.1×10⁵ to 10.0×10⁵ (Pa), respectively, to exhibit sufficient initial adhesion to the adherend, and releasability from the adherend after use. When the elastic modulus is too large, initial adhesion to the adherend may become insufficient. On the other hand, when the elastic modulus is too small, the cohesive force decreases and an adhesive residue may be left on the adherend upon releasing. Specifically, the elastic modulus can be adjusted taking into account that the elastic modulus increases when the amount of the (meth)acrylic acid is increased and/or a ratio of the glycidyl (meth)acrylate to the (meth)acrylate increases. Preferably, a loss tangent (tan δ) at 80° C. is preferably less than 0.5. When the loss tangent is within the above range, adhesive residual is not generally left because of sufficient crosslinking, namely, high cohesive force.

As used herein, “elastic modulus” means a storage elastic modulus G′ as measured in a shear mode under the conditions of a frequency of 1.0 Hz, a temperature within a range from −80 to 100° C. and a temperature rise rate of 5° C./min using a dynamic viscoelastometer. Also, the loss tangent (tan δ) means storage elastic modulus (G″)/storage elastic modulus (G′) obtained in the measurement.

The adhesive layer preferably has a thickness of 0.5 to 100 μm. When the adhesive layer has a thickness of less than 0.5 μm, the resulting film hardly conforms to the adherent when contacted with it and is likely to be released during use. On the other hand, when the adhesive layer has a thickness of more than 100 μm, it becomes hard to sufficiently remove the solvent after coating of the adhesive layer or foaming may occur when the adhesive layer is heat-treated.

In case the adhesion (anchoring property) between the heat resistant backing film layer and the adhesive layer is poor, delamination sometime occurs between the heat resistant backing film layer and the adhesive layer upon releasing the heat resistant masking tape from the adherent. In that case, one surface of the thermally resistant backing film layer may be subjected to a surface treatment for easy bonding using conventionally known technique. Preferred examples of the surface treatment include physical treatments such as corona discharge treatment, flame treatment, plasma treatment or ultraviolet irradiation treatment; or a wet chemical treatment. A corona discharge treatment is particularly preferred, since the heat resistant backing film layer subjected to the corona discharge treatment is commercially available and easily available.

In case the surface treatment is not conducted or the anchoring property is poor even after the surface treatment, a primer treatment may be conducted to further improve the anchoring property. The primer treatment refers to a treatment of providing a coating layer (primer layer) having excellent adhesion with both the heat resistant backing film layer and the adhesive layer, on the heat resistant backing film layer, and the adhesive layer can be provided on the primer layer. In that case, the thickness of the primer layer is preferably from 0.1 to 2 μm. When the thickness of the primer layer is 0.1 μm or less, its effect cannot be expected. On the other hand, when the thickness is 2 μm or more, solvents or chemicals can penetrate and delamination of the heat resistant masking tape and contamination of the adherend are likely to occur.

The surface of the heat resistant backing film layer opposite to the side on which the adhesive layer is disposed may be subjected to a release treatment. When the opposite side surface is subjected to a release treatment, the heat resistant masking tape of the present invention can be stored in the form of a rolled tape. As a release agent for release treatment, for example, a silicone-based release agent, a fluorine-based release agent, a (meth)acrylic release agent having a long-chain alkyl group and a vinyl ether-based release agent having a long-chain alkyl group can be used.

As far as the object and effect of the present invention are not adversely affected, the adhesive layer may contain additives such as antioxidants, ultraviolet absorbers, fillers (for example, inorganic fillers, conductive particles or pigments), lubricants such as waxes, tackifiers, plasticizers, curing accelerators and/or fluorescent dyes.

Next, an example of a method for preparing the above described heat resistant masking tape will be explained.

First, the above monomer mixture is polymerized. The monomer mixture can be radically polymerized in the presence of a polymerization initiator based on an azo compound or a peroxide. As the polymerization method, conventionally known polymerization methods such as solution polymerization method, emulsion polymerization method, suspension polymerization method and bulk polymerization method or the like can be used. Among these methods, the solution polymerization method is particularly preferred because an adhesive layer can be easily formed on the heat resistant backing film layer by coating and drying a solution containing the resulting polymer after polymerization. The solution polymerization is usually conducted in a nitrogen atmosphere at the polymerization temperature of 30 to 80° C. for the polymerization time of 1 to 24 hours. The polymer prepared as described above is dissolved in an organic solvent to prepare a coating solution. As the organic solvent, ethyl acetate, methyl ether ketone (MEK), toluene or a mixture thereof can be commonly used. Then, the coating solution is uniformly coated on the heat resistant backing film layer by a die coating method, a knife coating method, a bar coating method or other conventionally known coating methods. Since most of the coating solution is made only from the above polymer and a solvent it can easily realize uniform coating. Then, the solvent is removed by drying the coating solution, together with the heat resistant backing film layer. Then, polymer is crosslinked by heating the polymer on the heat resistant backing film layer. The drying step can also function as crosslinking step by heating at temperature of lower than 100° C. or lower. Alternatively, the crosslinking is preliminarily performed during the drying step and then proceeded additionally during an additional heating step. The crosslinking is occurred by reaction between a glycidyl group and carboxylic group in the polymer. However, crosslinking is not necessarily completely finished. For example, a sufficient adhesive strength, and releasability after use can be obtained by proceeding the reaction at temperature of 60 to 100° C. for several hours to about 3 days. When mixed with the curing accelerator such as phosphorus-based curing accelerator and the crosslinking is accelerated after the polymerization of the monomer mixture, it is not necessary to perform the above described crosslinking step (post curing). As described above, the heat resistant masking tape of the present invention can be prepared.

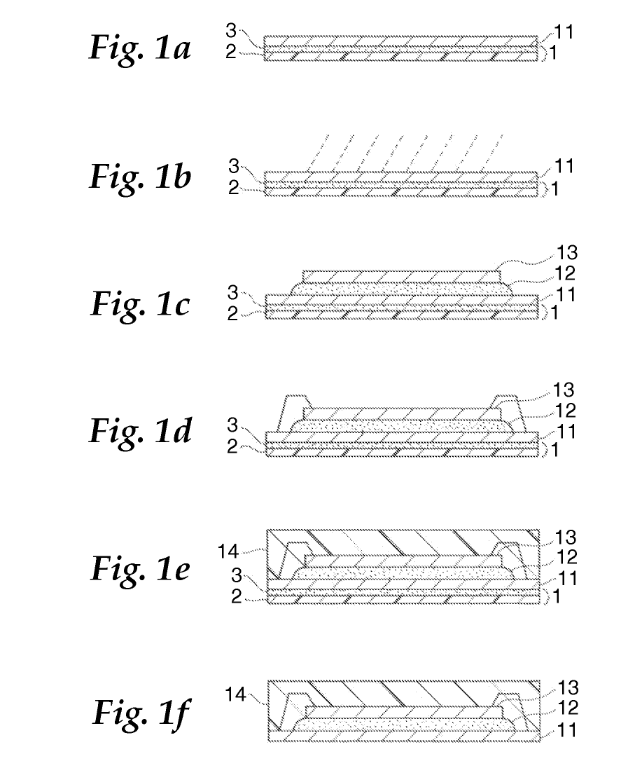

The heat resistant masking tape of the present invention is particularly useful as a masking tape which is laminated to a copper substrate or nickel-palladium alloy substrate for preventing a leakage of an epoxy molding compound (EMC) when a semiconductor chip on a lead frame is to be covered by molding. FIG. 1 shows one embodiment of manufacturing process flow diagram of a quad flat non-lead (QFN) chip scale package. First, the heat resistant masking tape 1 of the present invention having an adhesive layer 3 on the heat resistant backing film layer 2 is prepared. The heat resistant masking tape 1 and a lead frame 11 are laminated so that the backside of the lead frame 11 is in contact with the adhesive layer 3 of the masking tape 1 (step (a)). Thus, it is prevented that a molding compound is flowed from the lead frame 11 to the backside thereof through the openings of the lead frame 11 in later steps.

Next, the lead frame 11 is cleaned by plasma treatment such as argon plasma, argon/oxygen plasma, argon/hydrogen plasma, argon/nitrogen plasma in order to remove contaminants adhered on the lead frame 11 (step (b)). At this time, although the plasma bombards the adhesive layer 3 of the masking tape 1 of the present invention through the openings of the lead frame, the adhesive layer 3 of the masking tape 1 will not be released or will not occur an excessive increase in adhesion strength.

Next, a die-bonding tape adhesive 12 is coated on the lead frame 11, a semiconductor chip 13 is mounted thereon, and the die-bonding adhesive 12 is cured with heating (step (c)). The die-bonding tape 12 is commonly an epoxy-based thermosetting adhesive and is cured with treating at a temperature of 180 to 240° C. for about a few minutes to one hour.

After plasma cleaning as carried out in step (b), wire-bonding is performed (step (d)). The wire-bonding is typically to electrically connect an electrode pad on the chip to the leads, by a metal wire such as gold wire. The wire-bonding is commonly performed by melting a metal wire such as gold wire by, for example, spark and hot-pressing it onto the electrode on the chip. During this process, the laminate may be heated from 180° C. to 210° C. and in some cases, it is heated from 200° C. to 240° C.

Then, a resin-sealing step is performed by using an over-molding compound (step (e)). The over-molding compound is, for example, an epoxy-based thermosetting resin, namely, an epoxy molding compound (EMC). The fluidized resin is cured to a sealing resin 14 by heating it to about 160 to 240° C.

Next, the masking tape 1 attached to the lead frame 11 is released (step (f)). The properties of masking tape 1 of the present invention are not lowered by high temperature heat treatment and plasma treatment, and the tape retains stable adhesion strength. As a result, it is not delaminated and does not cause an excessive increase in adhesion strength. It does not leave any adhesive residue upon releasing on the lead frame 11, due to sufficiently low adhesion strength for releasing and sufficiently high cohesive strength of the adhesive.

After releasing the masking tape 1, usual procedures may be done to the resulting body. For example, it is solder plated, fixed on the dicing-tape and diced into individual packages.

### EXAMPLES

The present invention will be explained by way of examples. It is to be understood by a person with an ordinary skill in the art that the present invention is not limited to the examples.

### Examples 1 to 29 (Ex. 1 to 29) and Comparative Examples 1 to 7 (Comp. 1 to 7)

### Synthesis of Acrylic Copolymer

An acrylic copolymer having the following composition ratio as shown in the following Tables 1 and 2 was prepared by copolymerizing a monomer solution having a monomer concentration of 50% by weight in an ethyl acetate solvent. As an initiator, azobis(2,4-dimethylvaleronitrile) (V-65 (trade name) manufactured by Wako Pure Chemical Industries, Ltd.) was used in an amount of 0.25% by weight based on the weight of the monomers. Polymerization was performed at 55° C. in a water bath for 24 hours after nitrogen purging of a reactor.

TABLE 1
Composition of acrylic polymer

| | | | | SP value of | | Molecular weight | |
|---|---|---|---|---|---|---|---|
| | | | Molar ratio | copolymer (MPa^{0.5}) | | Mw | |
| | Composition | Parts by weight | GMA/AA | Before crosslinking | After crosslinking | (×10⁵) | Mw/Mn |
| PSA1 | BA:AA:GMA | 98.0:2.0:7.9 | 2.0 | 20.2 | 20.3 | 7.8 | 6.1 |
| PSA2 | 2EHA:AA:GMA | 98.0:2.0:7.9 | 2.0 | 19.2 | 19.3 | 8.6 | 8.3 |
| PSA3 | 2EHA:AA:GMA | 96.0:4.0:7.9 | 1.0 | 19.3 | 19.5 | 10.2 | 9.8 |
| PSA4 | 2EHA:AA:GMA | 94.0:6.0:7.9 | 0.7 | 19.4 | 19.6 | 8.0 | 9.0 |
| PSA5 | 2EHA:TBA:AA:GMA | 76.0:20.0:4.0:7.9 | 1.0 | 19.2 | 19.4 | 10.9 | 8.7 |
| PSA6 | 2EHA:TBA:AA:GMA | 68.0:30.0:2.0:7.9 | 2.0 | 19.1 | 19.2 | 8.0 | 7.3 |
| PSA7 | 2EHA:TBA:AA:GMA | 66.0:30.0:4.0:7.9 | 1.0 | 19.2 | 19.4 | 9.6 | 8.7 |
| PSA8 | 2EHA:TBA:AA:GMA | 56.0:40.0:4.0:7.9 | 1.0 | 19.2 | 19.4 | 9.8 | 8.7 |
| PSA9 | 2EHA:LA:AA:GMA | 59.0:39.0:2.0:7.9 | 2.0 | 19.0 | 19.1 | 8.0 | 7.9 |
| PSA10 | IOA:IBXA:AA:GMA | 80.0:16.0:4.0:7.9 | 1.0 | 19.3 | 19.5 | 10.5 | 10.2 |
| PSA11 | 2EHA:AA:GMA | 94.0:6.0:4.0 | 0.3 | 19.4 | 19.4 | 8.2 | 6.0 |
| PSA12 | 2EHA:AA:GMA | 92.0:8.0:5.9 | 0.4 | 19.5 | 19.7 | 8.7 | 7.5 |

TABLE 2
Material

| | SP value of copolymer (MPa^{0.5}) |
|---|---|
| Butyl acrylate (BA) | 20.0 |
| 2-ethylhexyl acrylate (2EHA) | 18.9 |
| Isooctyl acrylate (IOA) | 18.9 |
| Tert-butyl acrylate(TBA) | 18.5 |
| Lauryl acrylate (LA) | 18.7 |
| Isobornyl acrylate (IBXA) | 18.6 |
| Acrylic acid (AA) | 26.4 |
| Glycidyl methacrylate (GMA) | 22.0 |

### Solubility Parameter

According to the method of Fedors, the SP value was calculated only by a chemical structure (please refer to R. F. Fedors, A Method for Estimating Both the Solubility Parameters and Molar Volumes of Liquids, Polym. Eng. Sci., 14 (2), p. 147, 1974). Specifically, the SP value of the polymer constituting the adhesive layer was determined by the procedures shown in Tables 3 and 4.

TABLE 3
Calculation example of SP value of homopolymer

| | | Vaporization energy | | Molar volume | | Δei | Δvi | |
|---|---|---|---|---|---|---|---|---|
| | Group | Δei (cal/mol) | | Δvi (cal/mol) | Unit | (cal/mol) | (cal/mol) | |
| n-butyl acrylate | COO | 4300 | | 18 | 1 | 4300 | 18 | |
| | CH₃ | 1125 | | 33.5 | 1 | 1125 | 33.5 | |
| | CH₂ | 1180 | | 16.1 | 4 | 4720 | 64.4 | |
| | CH | 820 | | −1 | 1 | 820 | −1 | |
| ΣΔei | | 10965 | | | | | | |
| Σδvi | | 114.9 | | | | | | |
| (ΣΔei/ΣΔvi)^{0.5} | | 9.8 | (cal/cm³)^{0.5} | | | | | |
| (ΣΔei/ΣΔvi)^{0.5} | | 20.00 | MPa^{0.5} | | | | | |
| 2-ethylhexyl acrylate | COO | 4300 | | 18 | 1 | 4300 | 18 | |
| | CH₃ | 1125 | | 33.5 | 2 | 2250 | 67 | |
| | CH₂ | 1180 | | 16.1 | 6 | 7080 | 96.6 | |
| | CH | 820 | | −1 | 2 | 1640 | −2 | |
| ΣΔei | | 15270 | | | | | | |
| Σδvi | | 179.6 | | | | | | |
| (ΣΔei/ΣΔvi)^{0.5} | | 9.2 | (cal/cm³)^{0.5} | | | | | |
| (ΣΔei/ΣΔvi)^{0.5} | | 18.9 | MPa^{0.5} | | | | | |
| Acrylic acid | COOH | 6600 | | 28.5 | 1 | 6600 | 28.5 | |
| | CH₂ | 1180 | | 16.1 | 1 | 1180 | 16.1 | |
| | CH | 820 | | −1 | 1 | 820 | −1 | |
| | Tg > 25° C. | — | | 4 | 2 | | 8 | Atomic number |
| | | | | | | | | of main chain |
| | | | | | | | | skeleton |
| ΣΔei | | 8600 | | | | | | |
| Σδvi | | 51.6 | | | | | | |
| (ΣΔei/ΣΔvi)^{0.5} | | 12.9 | (cal/cm³)^{0.5} | | | | | |
| (ΣΔei/ΣΔvi)^{0.5} | | 26.4 | MPa^{0.5} | | | | | |
| Diglycidyl methacrylate | COO | 4300 | | 18 | 1 | 4300 | 18 | |
| | CH₃ | 1125 | | 33.5 | 1 | 1125 | 33.5 | |
| | CH₂ | 1180 | | 16.1 | 3 | 3540 | 48.3 | |
| | CH | 820 | | −1 | 1 | 820 | −1 | |
| | C | 350 | | 19.2 | 1 | 350 | −19.2 | |
| | D | 800 | | 3.8 | 1 | 800 | 3.8 | |
| | | 750 | | 18 | 1 | 750 | 1.8 | |
| ΣΔei | | 11685 | | | | | | |
| Σδvi | | 101.4 | | | | | | |
| (Σδei/Σδvi)^{0.5} | | 10.7 | (cal/cm³)^{0.5} | | | | | |
| (Σδei/Σδvi)^{0.5} | | 22.00 | Mpa^{0.5} | | | | | |
| 2-hydroxy-3-acryloyloxypropyl | COO | 4300 | | 18 | 2 | 8600 | 36 | |
| methacrylate (crosslinking | | | | | | | | |
| reaction product of acrylic | | | | | | | | |
| acid and glycidyl methacrylate | | | | | | | | |
| | CH₃ | 1125 | | 33.5 | 1 | 1125 | 33.5 | |
| | CH₂ | 1180 | | 16.1 | 4 | 4720 | 64.4 | |
| | CH | 820 | | −1 | 2 | 1640 | −2 | |
| | C | 350 | | −19.2 | 1 | 350 | −19.2 | |
| | OH | 5220 | | 13 | 1 | 5220 | 13 | |
| | Tg > 25° C. | | | 4 | 2 | | 8 | Atomic number |
| | | | | | | | | of main chain |
| | | | | | | | | skeleton |
| ΣΔei | | 21655 | | | | | | |
| Σδvi | | 133.7 | | | | | | |
| (ΣΔei/ΣΔvi)^{0.5} | | 12.7 | (cal/cm³)^{0.5} | | | | | |
| (ΣΔei/ΣΔvi)^{0.5} | | 26.0 | MPa^{0.5} | | | | | |

TABLE 4
Calculation example of SP value of adhesive polymer

| | Parts by weight | | Mol % | Mol | ΣΔei | Σδvi |
|---|---|---|---|---|---|---|
| PSA1 (Before crosslinking) | | | | | | |
| BA | 98.0 | | 90.18% | 0.766 | 9887.8 | 103.6 |
| AA | 2.0 | | 3.27% | 0.028 | 281.4 | 1.7 |
| GMA | 7.9 | | 6.55% | 0.056 | 765.7 | 6.6 |
| ΣΔei | 10934.8 | | | 0.849 | | |
| Σδvi | 111.9 | | | | | |
| (ΣΔei/ΣΔvi)^{0.5} | 9.9 | (Cal/cm³)^{0.5} | | | | |
| (ΣΔei/ΣΔvi)^{0.5} | 20.2 | MPa^{0.5} | | | | |
| PSA1 (After crosslinking) | | | | | | |
| BA | 98.0 | | 93.23% | 0.766 | 10223.2 | 107.1 |
| AA | 0.0 | | 0.00% | 0.000 | 0.0 | 0.0 |
| GMA | 3.9 | | 3.38% | 0.028 | 395.3 | 3.4 |
| Crosslinking reaction product | 5.9 | | 3.38% | 0.028 | 732.5 | 4.5 |
| ΣΔei | 11351.0 | | | 0.821 | | |
| Σδvi | 115.1 | | | | | |
| (ΣΔei/ΣΔvi)^{0.5} | 9.9 | (Cal/cm³)^{0.5} | | | | |
| (ΣΔei/ΣΔvi)^{0.5} | 20.3 | MPa^{0.5} | | | | |
| PSA2 (Before crosslinking) | | | | | | |
| 2EHA | 98.0 | | 86.45% | 0.533 | 13202.4 | 155.3 |
| AA | 2.0 | | 4.51% | 0.028 | 387.8 | 2.3 |
| GMA | 7.9 | | 9.03% | 0.056 | 1055.3 | 9.2 |
| ΣΔei | 14645.5 | | | 0.616 | | |
| Σδvi | 166.8 | | | | | |
| (ΣΔei/ΣΔvi)^{0.5} | 9.4 | (Cal/cm³)^{0.5} | | | | |
| (ΣΔei/ΣΔvi)^{0.5} | 19.2 | MPa^{0.5} | | | | |
| PSA2 (After crosslinking) | | | | | | |
| 2EHA | 98.0 | | 90.55% | 0.533 | 13827.7 | 162.6 |
| AA | 0.0 | | 0.00% | 0.000 | 0.0 | 0.0 |
| GMA | 3.9 | | 4.72% | 0.028 | 551.9 | 4.8 |
| Crosslinking reaction product | 5.9 | | 4.72% | 0.028 | 1022.7 | 6.3 |
| ΣΔei | 15402.2 | | | 0.588 | | |
| Σδvi | 173.7 | | | | | |
| (ΣΔei/ΣΔvi)^{0.5} | 9.4 | (Cal/cm³)^{0.5} | | | | |
| (ΣΔei/ΣΔvi)^{0.5} | 19.3 | MPa^{0.5} | | | | |

While a comparison between the SP values before and after the crosslinking was shown in Table 4, it is confirmed that the values of both cases are nearly the same.

### Measurement of Molecular Weight

A weight average molecular weight Mw, a number average molecular weight Mn and polydispersity Mw/Mn were measured by gel permeation chromatography (GPC) under the following conditions.

### Apparatus: HP-1090 SERIES II

### Diluent: Tetrahydrofuran (THF)

Column: PLgel MIXED-Ax2 (300 mm×7.5 mm, inner diameter (i.d.); 5 mm)

### Oven Temperature Room Temperature (25° C.)

Flow Rate: 1.0 mL/min

### Detector: Refractive Index

Sample Concentration: 0.1% (w/w)
Injection Volume: 50 microliter

### Calibrated Standard: Polystyrene

### Preparation of Masking Tape

As shown in the following Table 5, an adhesive solution was prepared by mixing 100 parts by weight of the solid content of the above described polymer with a predetermined amount of triphenylphosphine (TPP). The concentration of all solutions was adjusted to the concentration of the solid content of 30% by weight in toluene. A 25 μm thick polyimide film (Kapton 100V, manufactured by Du Pont-Toray Co., Ltd.) was coated with the adhesive solution, dried in an oven at 65° C. for 5 minutes and then laminated to a silicone-treated 50 μm thick polyethylene terephthalate (PET) film (Purex A50, manufactured by Teijin Dupont Co. Ltd.). The coating thickness of the adhesive was adjusted to 5 μm after drying. Further, as shown in Table 5, post curing was performed in an oven at 65° C. for 3 days so as to accelerate the crosslinking reaction, with respect to some tapes.

### Measurement of Viscoelasticity

A silicone-treated 50 μm thick polyethylene terephthalate (PET) film (Purex A50, manufactured by Teijin Dupont Co. Ltd.) was coated with the solution sample obtained above and then dried in an oven at 65° C. for 5 minutes to form a 5 μm thick adhesive layer. Using ARES manufactured by Rheometrix Co., a storage elastic modulus (G′), a storage elastic modulus (G″) and a loss tangent (tan δ) (storage elastic modulus (G″)/storage elastic modulus (G′)) were measured in a shear mode under the conditions of a frequency of 1.0 Hz, a temperature within a range from −80 to 100° C. and a temperature rise rate of 5° C./min. Also, a glass transition temperature (Tg) was determined as a peak temperature of the loss tangent (tan δ). The storage elastic modulus at 25 or 80° C. was compared with the value of tan δ at 80° C. In case of sufficient degree of crosslinking, the value of tan δis less than 0.5.

TABLE 5
Evaluation results of masking tape

| | | | | | Viscoelastic characteristics | | |
|---|---|---|---|---|---|---|---|
| | | | | | 25° c. | 80° c. | |
| | | Amount | | Tg | Storage elastic modulus G′ | Storage elastic modulus G′ | |
| | PSA | of TPP (phr) | Post curing | (° C.) | (×10⁵ pa) | (×10⁵ pa) | Tan δ |
| Comp. 1 | PSA1 | 0 | No | −25 | 0.82 | 0.26 | 0.66 |
| Comp. 2 | | 0 | Yes | −24 | 1.20 | 0.93 | 0.08 |
| Comp. 3 | | 1.0 | No | −23 | 1.56 | 1.55 | 0.04 |
| Comp. 4 | | 1.0 | Yes | −23 | 5.35 | 4.80 | 0.004 |
| Comp. 5 | PSA2 | 0 | No | −31 | 0.37 | 0.10 | 0.81 |
| Ex. 1 | | 0 | Yes | −31 | 0.68 | 0.62 | 0.05 |
| Ex. 2 | | 1.0 | No | −30 | 0.43 | 0.21 | 0.37 |
| Ex. 3 | | 1.0 | Yes | −30 | 2.58 | 2.88 | 0.003 |
| Comp. 6 | PSA3 | 0 | No | −23 | 0.47 | 0.13 | 0.72 |
| Ex. 4 | | 0 | Yes | −22 | 1.26 | 1.15 | 0.03 |
| Ex. 5 | | 0.5 | No | −24 | 0.49 | 0.19 | 0.48 |
| Ex. 6 | | 0.5 | Yes | −19 | 3.27 | 3.72 | 0.006 |
| Ex. 7 | | 1.0 | No | −23 | 0.49 | 0.19 | 0.49 |
| Ex. 8 | | 1.0 | Yes | −20 | 3.52 | 4.08 | 0.013 |
| Ex. 9 | | 1.5 | No | −23 | 0.58 | 0.31 | 0.29 |
| Ex. 10 | | 1.5 | Yes | −20 | 3.97 | 4.04 | 0.005 |
| Comp. 7 | PSA4 | 0 | No | −16 | 0.66 | 0.18 | 0.64 |
| Ex. 11 | | 0 | Yes | −8 | 1.88 | 1.67 | 0.02 |
| Ex. 12 | | 1.0 | No | −13 | 0.94 | 0.52 | 0.21 |
| Ex. 13 | | 1.0 | Yes | −8 | 5.70 | 5.38 | 0.009 |
| Ex. 14 | PSA5 | 1.0 | No | −10 | 1.49 | 0.90 | 0.11 |
| Ex. 15 | | 1.0 | Yes | −7 | 5.20 | 4.94 | 0.003 |
| Ex. 16 | PSA6 | 1.0 | No | −13 | 0.82 | 0.27 | 0.49 |
| Ex. 17 | | 1.0 | Yes | −9 | 3.01 | 2.71 | 0.002 |
| Ex. 18 | PSA7 | 1.0 | No | −4 | 1.60 | 0.76 | 0.14 |
| Ex. 19 | | 1.0 | Yes | 1 | 6.27 | 6.32 | 0.004 |
| Ex. 20 | PSA8 | 1.0 | No | 3 | 1.31 | 0.48 | 0.14 |
| Ex. 21 | | 1.0 | Yes | 10 | 9.80 | 7.28 | 0.004 |
| Ex. 22 | PSA9 | 1.0 | No | −37 | 0.33 | 0.24 | 0.17 |
| Ex. 23 | | 1.0 | Yes | −36 | 2.31 | 2.83 | 0.002 |
| Ex. 24 | PSA10 | 1.0 | No | −5 | 1.31 | 0.57 | 0.16 |
| Ex. 25 | | 1.0 | Yes | 0 | 7.22 | 6.75 | 0.006 |
| Ex. 26 | PSA11 | 0 | Yes | −10 | 0.92 | 0.93 | 0.05 |
| Ex. 27 | | 1.0 | Yes | −10 | 2.80 | 2.81 | 0.01 |
| Ex. 28 | PSA12 | 0 | Yes | −1 | 2.43 | 1.88 | 0.03 |
| Ex. 29 | | 1.0 | Yes | −2 | 5.09 | 4.19 | 0.01 |

In the above tables, Comparative Examples 1 to 4 (Comp. 1 to 3) are not within the scope of the present invention in the respect of the polymer composition because an n-butyl monomer having a SP value of 20.0 is used. Also, Comparative Examples 5 to 7 (Comp. 5 to 7) are not within the scope of the present invention in the respect of the fact that an acrylic polymer is not crosslinked because post curing is not performed and a curing accelerator is not added. This fact is contrastive to the fact that tan δdescribed hereinafter is 0.64 or more and tan δof the crosslinked polymers of Examples 1 to 25 (Ex. 1 to 25) is less than 0.5.

It is believed that all samples (examples and comparative examples) can sufficiently exhibit initial adhesion strength because Tg is 25° or lower and the elastic modulus at 25 or 80° C. is from 0.1×10⁵ to 10×10⁵ (Pa). It is believed that, when the tan δ exceeds 0.5, the degree of crosslinking is insufficient and thus an adhesive residue is left. When the tan δis 0.5 or less, the degree of crosslinking is sufficient and thus any adhesive residue is not left.

Measurements of Adhesion Strength (to Copper Plate) (Initial Adhesion Strength and Adhesion Strength after Heat Treatment)

The sample obtained above was slit into ones having a width of 25 mm and each of them was press-adhered to a copper plate (C1100, 1.0 mm thickness, manufactured by Nippon Tact K.K.) with 2 kg roller once being rolled back and forward. The press-adhered sample was left at room temperature for 20 minutes and its 90° peel adhesion strength (N/25 mm) was measured on a tensilon. The measurement was performed at a measurement rate of 300 mm/min at 25° C. This is called “initial adhesion strength”. The 90° peel adhesion strength (N/25 mm) was measured on a tensilon after the sample was press-adhered to the panel, left in an oven at 200° C. for 45 minutes, and left at room temperature for one hour. This is called “adhesion strength after heat treatment”. The results are shown in Table 6.

### Measurement of Adhesion Strength (to EMC)

On the tape sample obtained above, EMC (CEL-9200-HF10, manufactured by Hitachi Chemicals Co., Ltd.) was heat-pressed under the conditions of a pressure of 2.0 kgf/cm² and a temperature of 185° C. for 90 seconds. The pressed sample was left at room temperature for one hour and slit into ones having a width of 25 mm, and then the 90° peel adhesion strength (N/25 mm) was measured at a measurement rate of 300 mm/min at 25° C. The results are shown in Table 6.

### Application Test

The conditions encountered in the lead frame masking application used in the manufacturing of Quad Flat Non-Lead (QFN) chip scale packages (CSP) were simulated. Evaluation was made by the following processes 1 to 5 in order to check a leakage of EMC and an adhesive residue upon release of a tape. As a lead frame, a nickel palladium-plated copper frame was used.

Step 1: The masking tape obtained above was laminated to the lead frame so as not to incorporate bubbles between them.
Step 2: In order to simulate a heat curing of a die-attach epoxy adhesive and wire-bonding, the laminate was heat treated at 200° C. for 10 minutes.
Step 3: Melt molding and curing were performed using EMC (CEL-9200-HF10, manufactured by Hitachi Chemicals Co., Ltd.) were performed at 185° C. for 90 seconds.
Step 4: The tape was released.
Step 5: The tape peeled surface of the lead frame was observed by a microscope.

The results are shown in Table 6.

TABLE 6
Evaluation results of masking tape

| | | Adhesion strength (N/25 mm) | | | Application test | |
|---|---|---|---|---|---|---|
| | | Copper plate | | To | Surface of EMC | |
| | PSA | Initial | After heat treatment | EMC | Adhesive residue | Surface roughness |
| Comp. 1 | PSA1 | 3.9 | 1.5 | 6.6 | Much residue | Very rough |
| Comp. 2 | | 2.2 | 1.6 | 6.8 | Less residue | Rough |
| Comp. 3 | | 0.8 | 1.0 | 3.0 | Much residue | Very rough |
| Comp. 4 | | 0.3 | 0.6 | 1.9 | Less residue | Rough |
| Comp. 5 | PSA2 | 4.3 | 1.3 | 1.4 | Much residue | Rough |
| Ex. 1 | | 2.2 | 1.1 | 1.6 | None | Slightly rough |
| Ex. 2 | | 1.5 | 0.8 | 1.3 | None | Slightly rough |
| Ex. 3 | | 0.5 | 0.7 | 1.0 | None | Smooth |
| Comp. 6 | PSA3 | 3.7 | 1.3 | 1.3 | Much residue | Rough |
| Ex. 4 | | 1.9 | 1.1 | 1.0 | None | Slightly rough |
| Ex. 5 | | 2.6 | 1.4 | 1.5 | None | Slightly rough |
| Ex. 6 | | 0.6 | 1.0 | 1.3 | None | Smooth |
| Ex. 7 | | 0.9 | 0.9 | 1.0 | None | Slightly rough |
| Ex. 8 | | 0.4 | 0.9 | 1.1 | None | Smooth |
| Ex. 9 | | 1.5 | 1.3 | 1.1 | None | Slightly rough |
| Ex. 10 | | 0.5 | 0.7 | 0.9 | None | Smooth |
| Comp. 7 | PSA4 | 3.6 | 1.2 | 2.0 | Much residue | Slightly rough |
| Ex. 11 | | 1.9 | 1.1 | 2.8 | None | Smooth |
| Ex. 12 | | 1.9 | 1.2 | 1.6 | None | Smooth |
| Ex. 13 | | 0.8 | 0.7 | 1.8 | None | Smooth |
| Ex. 14 | PSA5 | 3.5 | 1.9 | 2.5 | None | Smooth |
| Ex. 15 | | 0.7 | 1.0 | 1.8 | None | Smooth |
| Ex. 16 | PSA6 | 3.3 | 2.2 | 2.8 | None | Slightly rough |
| Ex. 17 | | 0.7 | 1.3 | 1.4 | None | Smooth |
| Ex. 18 | PSA7 | 3.3 | 2.0 | 2.8 | None | Smooth |
| Ex. 19 | | 0.6 | 1.2 | 2.3 | None | Smooth |
| Ex. 20 | PSA8 | 3.9 | 2.3 | 3.9 | None | Smooth |
| Ex. 21 | | 0.7 | 1.0 | 2.9 | None | Smooth |
| Ex. 22 | PSA9 | 2.0 | 0.7 | 1.1 | None | Slightly rough |
| Ex. 23 | | 0.2 | 0.4 | 0.8 | None | Smooth |
| Ex. 24 | PSA10 | 2.1 | 1.8 | 2.8 | None | Slightly rough |
| Ex. 25 | | 0.7 | 1.4 | 2.6 | None | Smooth |
| Ex. 26 | PSA11 | 2.5 | 2.3 | 5.3 | None | Slightly rough |
| Ex. 27 | | 1.1 | 1.1 | 3.0 | None | Smooth |
| Ex. 28 | PSA12 | 2.1 | 2.0 | 4.7 | None | Slightly rough |
| Ex. 29 | | 1.2 | 1.3 | 4.0 | None | Smooth |

All masking tapes were not delaminated during the processes and also a leakage of EMC was not confirmed. Also, all making tapes were excellent in releasability of the tape from the copper frame, and contamination such as adhesive residue was not observed.

However, when the SP value of the polymer constituting the adhesive layer is high, like Comparative Examples 1 to 4, namely, n-butyl acrylate having a SP value of 20.0 MPa^{0.5} is used (more than 20.0 MPa^{0.5} in case of the entire polymer), affinity to EMC is high and therefore EMC is likely to melt-adhere. As a result, the surface of EMC was drastically roughened upon releasing a tape. This phenomenon is drastic in the sample which is not post cured, and an adhesive residue was left in Comparative Example 1. This shows poor cohesive strength of the adhesive layer, namely, sufficient crosslinking does not arise.

In the present invention, since a monomer in which the polymer constituting the adhesive layer has a low SP value, namely, a SP value of a homopolymer is 19 MPa^{0.5} or less is used as a main component (less than 20.0 MPa^{0.5} in case of the entire polymer), affinity to EMC is low and EMC is less likely to melt-adhere. As a result, it was found that any adhesive residue is not left on the surface of EMC and the surface of EMC is not roughened upon releasing a tape.

It was found that the addition of TPP dramatically accelerates the crosslinking reaction of the adhesive and only the mild drying step (at 65° C. for 5 minutes) upon coating with the adhesive imparts a required cohesive force. Therefore, it became unnecessary to perform post curing for a long time which was commonly required. When the sample containing TPP added therein is further post cured, it exhibited sufficient initial adhesion strength to an adherend and could be released without causing a large change in the adhesive strength after heat treatment. It was found that, when the masking tape of the present invention is used, the adherend is not contaminated with EMC and therefore the cleaning step is not required upon releasing the masking tape after use.

1. A heat resistant masking tape, comprising (1) a heat resistant backing film layer, and (2) a pressure-sensitive adhesive layer disposed on the heat resistant backing film layer, wherein the adhesive layer comprises a polymer having a solubility parameter (SP) value at 25° C. of 20 MPa^{0.5} or less.

2. A heat resistant masking tape, comprising (1) a heat resistant backing film layer, and (2) a pressure-sensitive adhesive layer disposed on the heat resistant backing film layer, wherein the adhesive layer comprises a polymer derived from polymerizing a monomer mixture comprising an alkyl (meth)acrylate, (meth)acrylic acid and glycidyl (meth)acrylate, wherein a solubility parameter (SP) value at 25° C. of a homopolymer of the alkyl(meth)acrylate is 19 MPa^{0.5} or less, wherein the alkyl (meth)acrylate is present in an amount of 90 to 99 parts by weight based on 100 parts by weight of the total weight of the alkyl (meth)acrylate and the (meth)acrylic acid, wherein the (meth)acrylic acid is present in an amount of 1 to 10 parts by weight based on 100 parts by weight of the total weight of the alkyl (meth)acrylate and the (meth)acrylic acid, and wherein the glycidyl (meth)acrylate is present in an amount of 0.25 to 2.5 mol based on 1 mol of the (meth)acrylic acid.

3. A heat resistant masking tape according to claim 1 or 2, wherein the alkyl (meth)acrylate is at least one selected from the group consisting of 2-ethylhexyl acrylate, isooctyl acrylate, lauryl acrylate, tert-butyl acrylate and isobornyl acrylate.

4. A heat resistant masking tape according to any one of claims 1 to 3, wherein the heat resistant backing film layer is of a material selected from the group consisting of polyethylene terephthalate (PET), polyetherimide, polyether sulfone, polyethylene naphthalate or polyphenylene sulfide, polyether ether ketone, polyamideimide and polyimide.

5. A method for producing a chip scale package, comprising the steps of laminating a masking tape and a lead frame, mounting a semiconductor chip on the lead frame, electrically connecting the chip, and resin-sealing the package using an overmolding compound, wherein the masking tape is the heat resistant masking tape described in any one of claims 1 to 4 and the overmolding compound is an epoxy molding compound (EMC).

6. A method for producing a chip scale package according to claim 5, wherein the epoxy molding compound (EMC) has a SP value at 25° C. is more than 20.0 MPa^{0.5} and no more than 26.0 MPa^{0.5}, and the polymer constituting the adhesive layer has a SP value of 20.0 MPa^{0.5} or less.
